(19) United States
(12) Patent Application Publication
(10) Pub. No.: US 2011/0063047 A1
(43) Pub. Date: Mar. 17, 2011

(54) BOUNDARY ACOUSTIC WAVE FILTER AND MULTIPLEXER HAVING THE SAME

(75) Inventor: Tetsuro OKUDA, Hakusan-shi (JP)

(73) Assignee: MURATA MANUFACTURING CO., LTD., Nagaokakyo-shi (JP)

(21) Appl. No.: 12/880,248

(22) Filed: Sep. 13, 2010

(30) Foreign Application Priority Data
Sep. 15, 2009 (JP) 2009-213359
Aug. 20, 2010 (JP) 2010-184522

(51) Int. Cl. H03H 9/72; H03H 9/64

(52) U.S. Cl. 333/133; 333/195

(57) ABSTRACT

A boundary acoustic wave filter includes an input terminal, an output terminal, a boundary acoustic wave filter unit connected between the input terminal and the output terminal, and a boundary acoustic wave resonator that is connected between the input terminal and the boundary acoustic wave filter unit and includes a piezoelectric substrate, a dielectric layer formed on the piezoelectric substrate, and an IDT electrode that is disposed at a boundary between the piezoelectric substrate and the dielectric layer and has a pair of comb-shaped electrodes interdigitated with each other. The number of pairs of electrode fingers in the IDT electrode in the boundary acoustic wave resonator is in a range of approximately 57.5 to approximately 77.5.

### BACKGROUND OF THE INVENTION

1. Field of the Invention

The present invention relates to boundary acoustic wave filters and multiplexers including the boundary acoustic wave filter, and, more particularly, to a boundary acoustic wave filter in which a boundary acoustic wave resonator is connected between an input terminal or an output terminal and a longitudinally coupled resonator-type elastic wave filter unit and a multiplexer including the boundary acoustic wave filter.

2. Description of the Related Art

An elastic wave filter is used as an RF or IF filter for mobile telephones, a VCO resonator, a VIF filter for TV sets, etc. The elastic wave filter is required to have a small insertion loss in a pass band and a high steepness of a filter characteristic on both sides of the pass band. Various techniques for reducing an insertion loss in a pass band and increasing the steepness of a filter characteristic on both sides of the pass band have been proposed.

For example, Japanese Unexamined Patent Application Publication No. 2003-69385 discloses a surface acoustic wave filter (hereinafter also referred to as a “shunt trap”) capable of increasing the flatness of an insertion loss in a pass band. In the surface acoustic wave filter, a surface acoustic wave resonator having a resonance point in the pass band of a longitudinally coupled resonator-type elastic wave filter unit is connected between the ground potential and the connection point between the longitudinally coupled resonator-type elastic wave filter unit and an input terminal.

In the surface acoustic wave filter disclosed in Japanese Unexamined Patent Application Publication No. 2003-69385, the shunt trap is disposed, and two surface acoustic wave resonators are connected in series between the input terminal and the longitudinally coupled resonator-type elastic wave filter unit. When two surface acoustic wave resonators are connected in series between an input terminal and a longitudinally coupled resonator-type elastic wave filter unit as disclosed in Japanese Unexamined Patent Application Publication No. 2003-69385, it is possible to enhance an impedance matching and reduce an insertion loss in a pass band. Accordingly, from the viewpoint of reducing an insertion loss in a pass band, it is desirable that two surface acoustic wave resonators be connected in series between an input terminal and a longitudinally coupled resonator-type elastic wave filter unit.

However, in order to achieve an impedance matching when two surface acoustic wave resonators are connected in series between an input terminal and a longitudinally coupled resonator-type elastic wave filter unit, it is necessary to increase the number of pairs of electrode fingers in IDT electrodes included in the two surface acoustic wave resonators. Accordingly, this case requires an electrode area that is approximately four times the area required in a case where a single surface acoustic wave resonator is connected between an input terminal and a longitudinally coupled resonator-type elastic wave filter unit. This leads to the increase in the size of the elastic wave filter.

### SUMMARY OF THE INVENTION

Preferred embodiments of the present invention provide a small boundary acoustic wave filter having a small insertion loss in a pass band.

A boundary acoustic wave filter according to a preferred embodiment of the present invention includes an input terminal, an output terminal, a longitudinally coupled resonator-type boundary acoustic wave filter unit connected between the input terminal and the output terminal, and a boundary acoustic wave resonator that is connected between the input terminal or the output terminal and the longitudinally coupled resonator-type boundary acoustic wave filter unit and includes a piezoelectric substrate, a first dielectric layer disposed on the piezoelectric substrate, and an IDT electrode that is disposed at a boundary between the piezoelectric substrate and the first dielectric layer and includes a pair of comb-shaped electrodes interdigitated with each other. The number of pairs of electrode fingers in the IDT electrode in the boundary acoustic wave resonator is preferably in a range of approximately 57.5 to approximately 77.5.

In the boundary acoustic wave filter, the boundary acoustic wave resonator preferably is connected between the input terminal and the longitudinally coupled resonator-type boundary acoustic wave filter unit.

In the boundary acoustic wave filter, the piezoelectric substrate preferably is a LiNbO₃ substrate. As a result, a relatively large electromechanical coupling coefficient can be obtained. It is therefore possible to broaden a pass band.

In the boundary acoustic wave filter, the boundary acoustic wave resonator further includes a second dielectric layer disposed between the piezoelectric substrate and the IDT electrode. As a result, it is possible to improve a surge resistance of the boundary acoustic wave filter.

In the boundary acoustic wave filter, the number of the boundary acoustic wave resonators disposed between the input terminal or the output terminal and the longitudinally coupled resonator-type boundary acoustic wave filter unit preferably is one.

A multiplexer according to a preferred embodiment of the present invention includes a transmitter filter and a receiver filter. At least one of the transmitter filter and the receiver filter is the above-described boundary acoustic wave filter according to a preferred embodiment of the present invention.

In a preferred embodiment of the present invention, since the number of pairs of electrode fingers in an IDT electrode in a boundary acoustic wave resonator preferably is in the range of approximately 57.5 to approximately 77.5, it is possible to reduce an insertion loss in a pass band with a single boundary acoustic wave resonator disposed between an input terminal or an output terminal and a boundary acoustic wave filter unit. Accordingly, according to a preferred embodiment of the present invention, it is possible to provide a small boundary acoustic wave filter capable achieving a small insertion loss in a pass band and a multiplexer including the boundary acoustic wave filter.

The above and other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a schematic diagram illustrating the configuration of a duplexer according to a preferred embodiment of the present invention.

FIG. 2 is a partially enlarged cross-sectional view of a duplexer according to a preferred embodiment of the present invention.

FIG. 3 is a schematic plan view of a series trap.

FIG. 4 is a graph illustrating an insertion loss (represented by alternate long and short dashed lines) in the pass band of a receiver filter in the case of the single-stage connection of a series trap (having approximately 46 pairs of electrode fingers and the cross width of approximately 33.6λ) and an insertion loss (represented by a solid line) in the pass band of a receiver filter in the case of the two-stage connection of series traps (having approximately 92.5 pairs of electrode fingers and the cross width of approximately 33.6λ).

FIG. 5 is a graph illustrating the impedance characteristic (represented by alternate long and short dashed lines) of a series trap (having approximately 46 pairs of electrode fingers and the cross width of approximately 33.6λ) and the impedance characteristic (represented by a solid line) obtained in the case of the two-stage connection of series traps (having approximately 92.5 pairs of electrode fingers and the cross width of approximately 33.6λ).

FIG. 6 is a graph representing the phase characteristic (represented by alternate long and short dashed lines) of a series trap (having approximately 46 pairs of electrode fingers and the cross width of approximately 33.6λ) and the phase characteristic (represented by a solid line) obtained in the case of the two-stage connection of series traps (having approximately 92.5 pairs of electrode fingers and the cross width of approximately 33.6λ).

FIG. 7 is a graph illustrating the relationship between the number of pairs of electrode fingers in an IDT electrode and an impedance ratio.

FIG. 8 is a graph illustrating an insertion loss (represented by a solid line) in the pass band of a reception filter according to a preferred embodiment of the present invention (in which the number of pairs of electrode fingers in a series trap is 67) and an insertion loss (represented by alternate long and short dashed lines) in the pass band of a reception filter in the case of the single-stage connection of a series trap having approximately 46 pairs of electrode fingers in a comparative example.

### DETAILED DESCRIPTION OF THE PREFERRED EMBODIMENTS

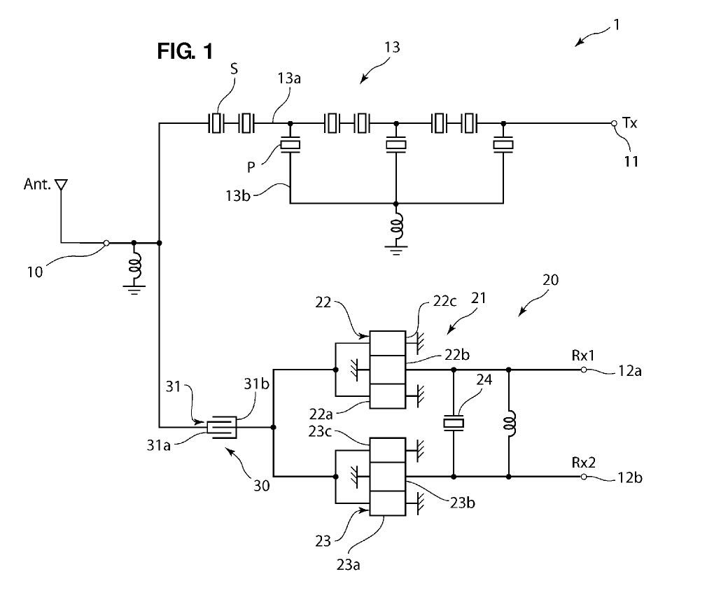

A preferred embodiment of the present invention will be described below with a duplexer 1 illustrated in FIG. 1. In FIG. 1, for illustrative convenience, some of the IDT electrodes are substantially rectangular, some of the reflectors are not illustrated, and the numbers of electrode fingers in an IDT electrode and a reflector are different from actual numbers.

As illustrated in FIG. 1, the duplexer 1 includes an antenna terminal 10 connected to an antenna Ant, a transmission terminal 11 connected to a transmission signal terminal Tx, a receiving terminal 12a connected to a receiving signal terminal Rx1, and a receiving terminal 12b connected to a receiving signal terminal Rx2. In a preferred embodiment of the present invention, the transmission band of approximately 880 MHz to approximately 915 MHz and the receiving band of approximately 925 MHz to approximately 960 MHz are set, for example.

A transmitter filter 13 is connected between the antenna terminal 10 and the transmission terminal 11. A transmission signal is input from the transmission terminal 11 and is output from the antenna terminal 10. That is, in this case, the transmission terminal 11 functions as an input terminal, and the antenna terminal 10 functions as an output terminal. The transmitter filter 13 preferably is a ladder filter including a series arm 13a arranged to connect the antenna terminal 10 and the transmission terminal 11 with each other and a plurality of parallel arms 13b connected between the series arm 13a and the ground potential. In the series arm 13a, a plurality of series-arm resonators S are connected in series. Each of the parallel arms 13b is provided with a parallel-arm resonator P.

A receiver filter 20 is connected between the antenna terminal 10 and each of the receiving terminals 12a and 12b. A receiving signal is input from the antenna terminal 10 and is output from the receiving terminals 12a and 12b. That is, in this case, the antenna terminal 10 functions as an input terminal and the receiving terminals 12a and 12b function as output terminals. In a preferred embodiment of the present invention, the receiver filter 20 preferably is a boundary acoustic wave filter. The receiver filter 20 includes a longitudinally coupled resonator-type boundary acoustic wave filter unit 21 connected between the antenna terminal 10 and each of the receiving terminals 12a and 12b. The boundary acoustic wave filter unit 21 includes a first filter unit 22 and a second filter unit 23.

The first filter unit 22 is connected between the antenna terminal 10 and the receiving terminal 12a, and includes a first IDT electrode 22a, a second IDT electrode 22b, and a third IDT electrode 22c. The IDT electrodes 22a to 22c are disposed along a boundary acoustic wave propagation direction. Although not illustrated in FIG. 1, a grating-type reflector is disposed on either side of the boundary acoustic wave propagation direction in which the IDT electrodes 22a to 22c are disposed. Each of the IDT electrodes 22a to 22c includes a pair of comb-shaped electrodes that are interdigitated with each other. One of the comb-shaped electrodes in each of the first IDT electrode 22a and the third IDT electrode 22c is connected to the antenna terminal 10, and the other one of the comb-shaped electrodes in each of the first IDT electrode 22a and the third IDT electrode 22c is connected to the ground potential. One of the comb-shaped electrodes in the second IDT electrode 22b is connected to the ground potential, and the other one of the comb-shaped electrodes in the second IDT electrode 22b is connected to the receiving terminal 12a.

The second filter unit 23 is connected between the antenna terminal 10 and the receiving terminal 12b, and includes a first IDT electrode 23a, a second IDT electrode 23b, and a third IDT electrode 23c. The IDT electrodes 23a to 23c are disposed along a boundary acoustic wave propagation direction. Although not illustrated in FIG. 1, a grating-type reflector is disposed on either side of the boundary acoustic wave propagation direction in which the IDT electrodes 23a to 23c are disposed. Each of the IDT electrodes 23a to 23c includes a pair of comb-shaped electrodes that are interdigitated with each other. One of the comb-shaped electrodes in each of the first IDT electrode 23a and the third IDT electrode 23c is connected to the antenna terminal 10, and the other one of the comb-shaped electrodes in each of the first IDT electrode 23a and the third IDT electrode 23c is connected to the ground potential. One of the comb-shaped electrodes in the second IDT electrode 23b is connected to the ground potential, and the other one of the comb-shaped electrodes in the second IDT electrode 23b is connected to the receiving terminal 12b.

A boundary acoustic wave resonator 24 that is a shunt trap is connected between the connection point between the second IDT electrode 23b and the receiving terminal 12b and the connection point between the second IDT electrode 22b and the receiving terminal 12a.

A boundary acoustic wave resonator 30 is disposed between the antenna terminal 10 and the boundary acoustic wave filter unit 21. In this specification, a boundary acoustic wave resonator connected between an input terminal or an output terminal and a boundary acoustic wave filter unit is also referred to as a “series trap.”

The resonant frequency of the series trap 30 is in the pass band of the receiver filter 20, and the anti-resonant frequency of the series trap 30 is in a stop band on the higher-frequency side of the pass band of the receiver filter 20. Accordingly, it is possible to improve the steepness of a filter characteristic with the series trap 30.

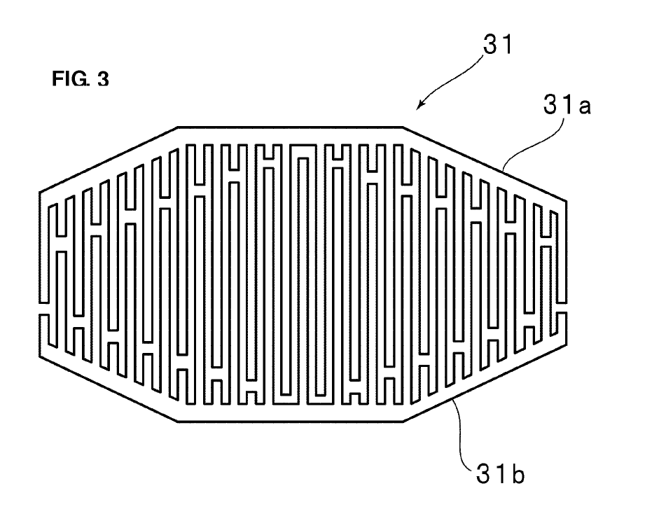

The boundary acoustic wave resonator 30 includes an IDT electrode 31. The IDT electrode 31 includes a pair of comb-shaped electrodes 31a and 31b that are weighted and are interdigitated with each other as illustrated in FIG. 3.

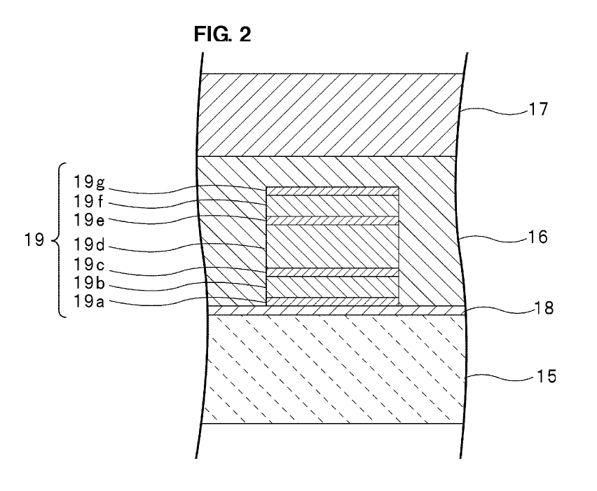

Next, the layer structure of the duplexer 1 according to a preferred embodiment of the present invention will be described with reference to FIG. 2. As illustrated in FIG. 2, the duplexer 1 is provided with a piezoelectric substrate 15. A substrate formed of a piezoelectric material can be used as the piezoelectric substrate 15. The piezoelectric substrate 15 preferably is, for example, a LiNbO₃ substrate or a LiTaO₃ substrate.

On the piezoelectric substrate 15, a first dielectric layer 16 and a second dielectric layer 17 are formed in this order. The first dielectric layer 16 has an acoustic velocity lower than that of the second dielectric layer 17. The material of each of the first dielectric layer 16 and the second dielectric layer 17 may be any material. For example, the first dielectric layer 16 can be made of silicon oxide such as SiO₂, and the second dielectric layer 17 can be made of silicon nitride such as SiN. The thickness of each of the first dielectric layer 16 and the second dielectric layer 17 may be any thickness with which a boundary acoustic wave preferably is excited. For example, the thickness of the first dielectric layer 16 preferably is in a range of approximately 500 nm to approximately 2000 nm, and the thickness of the second dielectric layer 17 preferably is in a range of approximately 1000 nm to approximately 4000 nm.

An electrode 19 is disposed at the boundary between the piezoelectric substrate 15 and the first dielectric layer 16. The electrode 19 defines the above-described IDT electrodes including the IDT electrode 31 and the above-described grating reflectors. The material of the electrode 19 may be any conductive material. The electrode 19 is made of, for example, metal or an alloy. The electrode 19 may include a single conductive layer or the laminate of a plurality of conductive layers. More specifically, in a preferred embodiment of the present invention, the electrode 19 includes adhesive layers 19a, 19c, 19e, and 19g which are made of Ti, a first conductive layer 19b and a third conductive layer 19f which are made of Pt, and a second conductive layer 19d made of AlCu. The thickness of each of the layers 19a to 19g may be any thickness. For example, the thicknesses of the adhesive layers 19a, 19c, 19e, and 19g preferably are in the range of approximately 5 nm to approximately 50 nm, the thicknesses of the first conductive layer 19b and the third conductive layer 19f are preferably in the range of approximately 5 nm to approximately 150 nm, and the thickness of the second conductive layer 19d is preferably in the range of approximately 50 nm to approximately 700 nm.

In a preferred embodiment of the present invention, in order to improve a surge resistance, a dielectric layer 18 is disposed between the electrode 19 and the piezoelectric substrate 15. The dielectric layer 18 may be made of any dielectric, for example, Ta₂O₅. The thickness of the dielectric layer 18 may be any thickness, and preferably is, for example, in the range of approximately 5 nm to approximately 60 nm.

In a preferred embodiment of the present invention, the number of pairs of electrode fingers in the IDT electrode 31 in the boundary acoustic wave resonator 30 preferably is in the range of approximately 57.5 to approximately 77.5. Accordingly, it is possible to reduce an insertion loss in a pass band with a single boundary acoustic wave resonator, that is, the boundary acoustic wave resonator 30. Both the size reduction and the reduction in an insertion loss in a pass band can therefore be achieved. The reason for this will be described in detail below.

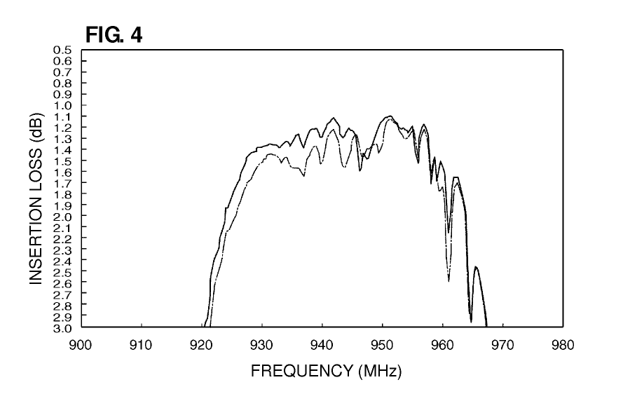

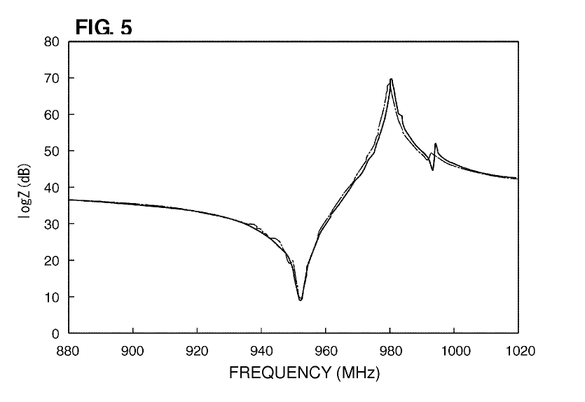

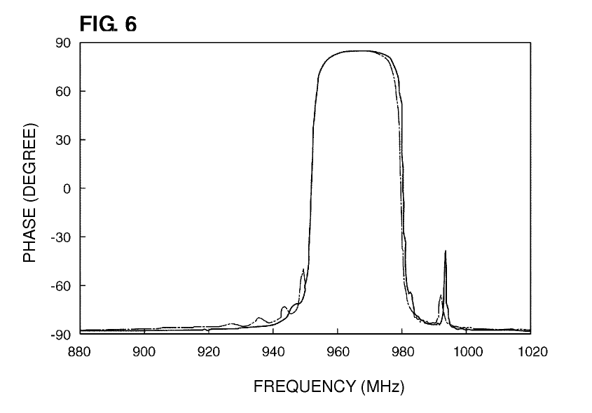

FIG. 4 is a graph illustrating an insertion loss in the pass band of a receiver filter in the case of the single-stage connection of a series trap (having approximately 46 pairs of electrode fingers and the cross width of approximately 33.6λ) and an insertion loss in the pass band of a receiver filter in the case of the two-stage connection of series traps (having approximately 92.5 pairs of electrode fingers and the cross width of approximately 33.6λ). Referring to FIG. 4, a solid line represents an insertion loss in the pass band of a reception filter in the case of the two-stage connection of series traps (having approximately 92.5 pairs of electrode fingers and the cross width of approximately 33.6λ), and alternate long and short dashed lines represent an insertion loss in the pass band of a receiver filter in the case of the single-stage connection of a series trap (having approximately 46 pairs of electrode fingers and the cross width of approximately 33.6λ). FIG. 5 is a graph illustrating the impedance characteristic of a series trap (having approximately 46 pairs of electrode fingers and the cross width of approximately 33.6λ) and the impedance characteristic obtained in the case of the two-stage connection of series traps (having approximately 92.5 pairs of electrode fingers and the cross width of approximately 33.6λ). Referring to FIG. 5, a solid line represents the impedance characteristic obtained in the case of the two-stage connection of series traps (having approximately 92.5 pairs of electrode fingers and the cross width of approximately 33.6λ), and alternate long and short dashed lines represent the impedance characteristic of a series trap (having approximately 46 pairs of electrode fingers and the cross width of approximately 33.6λ). In FIG. 5, a vertical axis represents the logarithm (log Z) of an impedance (Z). FIG. 6 is a graph representing the phase characteristic of a series trap (having approximately 46 pairs of electrode fingers and the cross width of approximately 33.6λ) and the phase characteristic obtained in the case of the two-stage connection of series traps (having approximately 92.5 pairs of electrode fingers and the cross width of approximately 33.6λ). Referring to FIG. 6, a solid line represents the phase characteristic obtained in the case of the two-stage connection of series traps (having approximately 92.5 pairs of electrode fingers and the cross width of approximately 33.6λ), and alternate long and short dashed lines represent the phase characteristic of a series trap (having approximately 46 pairs of electrode fingers and the cross width of approximately 33.6λ).

As illustrated in FIG. 5, in the case of the single-stage connection of a series trap, a resistance (hereinafter referred to as a “resonant resistance”) in the vicinity of a resonant frequency tends to be larger than that obtained in the case of the two-stage connection of series traps. When a resonant resistance is increased, the amount of displacement from −90° in the phase on the lower-frequency side of a resonance point tends to increase as illustrated in FIG. 6. Accordingly, the series trap operates as a capacitor with a loss. As a result, as illustrated in FIG. 4, an insertion loss is increased on the lower-frequency side in the pass band in the case of the single-stage connection of a series trap.

As illustrated in FIG. 5, in the case of the single-stage connection of a series trap, a resistance (hereinafter referred to as an “anti-resonant resistance”) in the vicinity of an anti-resonant frequency tends to be smaller than that obtained in the case of the two-stage connection of series traps. When an anti-resonant resistance is reduced, the amount of displacement from 90° in the phase in the vicinity of an anti-resonant frequency tends to increase as illustrated in FIG. 6. Accordingly, the series trap operates as an inductor with a loss. As a result, as illustrated in FIG. 4, an insertion loss is increased on the higher-frequency side in the pass band in the case of the single-stage connection of a series trap.

In order to reduce an insertion loss in a pass band, it is therefore necessary to reduce the resonant resistance of a series trap and increase the anti-resonant resistance of the series trap. That is, it is necessary to increase an impedance ratio obtained by dividing an anti-resonant resistance by a resonant resistance.

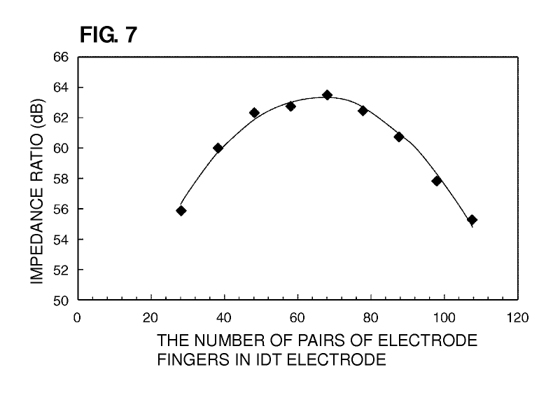

A resonant resistance and an anti-resonant resistance are significantly affected by the cross width of the IDT electrode 31 and the number of pairs of electrode fingers in the IDT electrode 31. The cross width of the IDT electrode 31 and the number of pairs of electrode fingers in the IDT electrode 31 are also factors in determining the impedance of the series trap 30. More specifically, the impedance of the series trap 30 is the product of the cross width of the IDT electrode 31 and the number of pairs of electrode fingers in the IDT electrode 31. Since an impedance required for the series trap 30 is a constant impedance, the product of the cross width of the IDT electrode 31 and the number of pairs of electrode fingers in the IDT electrode 31 is determined by a required impedance. Accordingly, when one of the cross width of the IDT electrode 31 and the number of pairs of electrode fingers in the IDT electrode 31 is determined, the other one of the cross width of the IDT electrode 31 and the number of pairs of electrode fingers in the IDT electrode 31 can be determined with a required impedance. The inventors of the present invention calculated a range in which an optimal impedance ratio could be obtained by experiments under conditions where an obtained impedance was constant, the number of pairs of electrode fingers in the IDT electrode 31 was set as a parameter, and only a single series trap, the series trap 30, was disposed. A result of the experiments is illustrated in Table 1 and FIG. 7.

TABLE 1

| The number of pairs of | | |
|---|---|---|
| electrode fingers in an | | |
| IDT electrode (pair) | Cross width (λ) | Impedance ratio (dB) |
| 107.5 | 18.1 | 55.2 |
| 97.5 | 19.9 | 57.8 |
| 87.5 | 22.2 | 60.8 |
| 77.5 | 25.0 | 62.5 |
| 67.5 | 28.7 | 63.5 |
| 57.5 | 33.6 | 62.8 |
| 47.5 | 40.6 | 62.3 |
| 37.5 | 51.3 | 60.0 |
| 27.5 | 69.7 | 55.8 |

It is discovered from an experimental result illustrated in Table 1 and FIG. 7 that an obtained impedance ratio becomes low when the number of pairs of electrode fingers in the IDT electrode 31 is too small or too large. When the number of pairs of electrode fingers in the IDT electrode 31 was in the range of 57.5 to 77.5, a high impedance ratio equal to or higher than 62.5 dB was obtained. When the number of pairs of electrode fingers in the IDT electrode 31 was in the vicinity of 67.5, the highest impedance ratio was obtained. Accordingly, by setting the number of pairs of electrode fingers in the IDT electrode 31 to a value in the range of approximately 57.5 to approximately 77.5, a high impedance ratio can be obtained even when only a single series trap, the series trap 30, is disposed. As a result, it is possible to effectively reduce an insertion loss in a pass band without increasing the size of a filter.

The stop band of an excited elastic wave is determined in accordance with a wavelength that is determined by an electrode finger pitch. Accordingly, it is considered that the desired range of the number of pairs of electrode fingers in IDT electrode 31 does not depend on the frequency of an elastic wave.

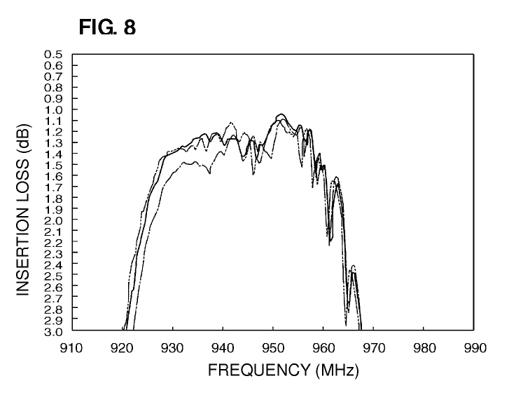

In order to check an effect obtained by setting the number of pairs of electrode fingers in the IDT electrode 31 to a value in the range of approximately 57.5 to approximately 77.5, the receiver filter 20 was produced in accordance with the following design parameter and the filter characteristic of the receiver filter 20 was measured. A result of the measurement is illustrated in FIG. 8. In the following description of a design parameter, for the convenience of explanation, the same reference numerals as in a preferred embodiment of the present invention denote the same elements in a comparative example.

Referring to FIG. 8, a solid line represents the insertion loss of the reception filter 20 according to a preferred embodiment of the present in which the number of pairs of electrode fingers in a series trap is 67, alternate long and short dashed lines represent the insertion loss of a reception filter in a comparative example in the case of the single-stage connection of a series trap having approximately 46 pairs of finger electrodes, and a chain double-dashed line represents the insertion loss of the reception filter in the case of the two-stage connection of series traps (having approximately 92.5 pairs of finger electrodes and the cross width of approximately 33.6λ).

As is apparent from FIG. 8, by setting the number of pairs of electrode fingers in the IDT electrode 31 to a value in the range of approximately 57.5 to approximately 77.5, it is possible to reduce an insertion loss in a pass band to the same level as that obtained in the case of the two-stage connection of series traps. Accordingly, a filter can be miniaturized without degrading a filter characteristic.

### Design Parameters in Preferred Embodiments

The series trap 30;

the number of pairs of electrode fingers: 67
cross width: 25λ (93 μm)
the number of electrode fingers: 135
the wavelength (λ) determined by an electrode finger pitch: 3.72 μm
duty: 0.47
no reflector

The boundary acoustic wave filter unit 21;

the wavelength (λ) in a reflector: 3.94 μm
the number of electrode fingers in the reflector: 23
the number of pairs of electrode fingers in the reflector: 11
the number of electrode fingers in the IDT electrodes 22a, 22c, 23a, and 23c: 53 (the number of electrode fingers in a narrow-pitch electrode finger portion adjacent to the IDT electrodes 22b and 23b: 8)
the wavelength (λ) in a portion other than the narrow-pitch electrode finger portion in the IDT electrodes 22a, 22c, 23a, and 23c: 3.91 μm
the wavelength (λ) in the narrow-pitch electrode finger portion in the IDT electrodes 22a, 22c, 23a, and 23c: 3.69 μm
the number of pairs of electrode fingers in the portion other than the narrow-pitch electrode finger portion in the IDT electrodes 22a, 22c, 23a, and 23c: 22
the number of pairs of electrode fingers in the narrow-pitch electrode finger portion in the IDT electrodes 22a, 22c, 23a, and 23c: 3.5
the number of electrode fingers in the IDT electrodes 22b and 23b: 35 (the number of electrode fingers in a narrow-pitch electrode finger portion adjacent to the IDT electrodes 22a, 22c, 23a, and 23c: 7)
the wavelength (λ) in a portion other than the narrow-pitch electrode finger portion in the IDT electrodes 22b and 23b: 3.83 μm
the wavelength (λ) in the narrow-pitch electrode finger portion in the IDT electrodes 22b and 23b: 3.65 μm
the number of pairs of electrode fingers in the portion other than the narrow-pitch electrode finger portion in the IDT electrodes 22b and 23b: 10
the number of pairs of electrode fingers in the narrow-pitch electrode finger portion in the IDT electrodes 22b and 23b: 3
duty: 0.47
propagation angle: 0°

The shunt trap 24;

cross width: 29.3λ (115 μm)
the wavelength (λ) in a reflector: 3.92 μm
the number of electrode fingers in the reflector: 21
the number of pairs of electrode fingers in the reflector: 10
the wavelength (λ) in an IDT electrode: 3.92 μm
the number of electrode fingers in the IDT electrode: 51
the number of pairs of electrode fingers in the IDT electrode: 25
duty: 0.47

### Design Parameters in Comparative Example

The series trap 30;
the number of pairs of electrode fingers: 46
cross width: 33.6λ

Other design parameters are the same as those described above.

### Modifications to Preferred Embodiments

In a preferred embodiment of the present invention, a duplexer is preferably used as a multiplexer. However, for example, a triplexer may be used as a multiplexer.

In a preferred embodiment of the present invention, a 3-IDT-type longitudinally coupled resonator-type boundary acoustic wave filter unit is used. However, for example, a 5-IDT-type or 7-IDT-type longitudinally coupled resonator-type boundary acoustic wave filter unit may be used.

In a preferred embodiment of the present invention, the boundary acoustic wave resonator 30 that is a series trap is preferably connected between the antenna terminal 10 that is an input terminal and the boundary acoustic wave filter unit 21. However, for example, a boundary acoustic wave resonator that is a series trap may be connected between an output terminal and a boundary acoustic wave filter unit.

In a preferred embodiment of the present invention, a series trap has no reflector. However, the series trap may have a reflector.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A boundary acoustic wave filter comprising:
an input terminal;
an output terminal;
a longitudinally coupled resonator-type boundary acoustic wave filter unit connected between the input terminal and the output terminal; and
a boundary acoustic wave resonator connected between the input terminal or the output terminal and the longitudinally coupled resonator-type boundary acoustic wave filter unit and includes a piezoelectric substrate, a first dielectric layer disposed on the piezoelectric substrate, and an IDT electrode disposed at a boundary between the piezoelectric substrate and the first dielectric layer and includes a pair of comb-shaped electrodes interdigitated with each other; wherein
a number of pairs of electrode fingers in the IDT electrode in the boundary acoustic wave resonator is in a range of approximately 57.5 to approximately 77.5.

2. The boundary acoustic wave filter according to claim 1, wherein the boundary acoustic wave resonator is connected between the input terminal and the longitudinally coupled resonator-type boundary acoustic wave filter unit.

3. The boundary acoustic wave filter according to claim 1, wherein the piezoelectric substrate is an LiNbO₃ substrate.

4. The boundary acoustic wave filter according to claim 1, wherein the boundary acoustic wave resonator further includes a second dielectric layer disposed between the piezoelectric substrate and the IDT electrode.

5. The boundary acoustic wave filter according to claim 1, wherein a number of the boundary acoustic wave resonators disposed between the input terminal or the output terminal and the longitudinally coupled resonator-type boundary acoustic wave filter unit is one.

6. A multiplexer comprising:
a transmitter filter; and
a receiver filter; wherein
at least one of the transmitter filter and the receiver filter is the boundary acoustic wave filter according to claim 1.
